(19) United States
(12) Patent Application Publication
(10) Pub. No.: US 2022/0210905 A1
(43) Pub. Date: Jun. 30, 2022

(54) ELECTRONIC DEVICE INCLUDING HEAT DISSIPATION STRUCTURE

(71) Applicant: Samsung Electronics Co., Ltd., Suwon-si (KR)

(72) Inventors: Chunsik CHOI, Suwon-si (KR); Jeongwon PARK, Suwon-si (KR); Youngho YOON, Suwon-si (KR); Jongmin YOON, Suwon-si (KR); Jungkeun LEE, Suwon-si (KR); Sangchul JUNG, Suwon-si (KR)

(21) Appl. No.: 17/572,468

(22) Filed: Jan. 10, 2022

Related U.S. Application Data
(63) Continuation of application No. PCT/KR2021/020026, filed on Dec. 28, 2021.

(30) Foreign Application Priority Data
Dec. 30, 2020 (KR) 10-2020-0188341

(51) Int. Cl. H05K 1/02; H05K 1/14; G02B 27/01; G02C 11/00

(52) U.S. Cl. CPC H05K 1/0203; H05K 1/144; G02B 27/0176; G02B 2027/0138; H05K 2201/042; G02B 2027/0178; G02C 11/10

(57) ABSTRACT

In an electronic device includes a heat dissipation structure. The heat dissipation structure may include: a first printed circuit board; a second printed circuit board spaced apart from the first printed circuit board to form a space; a first interposer and a second interposer together surrounding the space; at least one electronic component disposed in the space and mounted on the first printed circuit board; a first thermal interface material (TIM) combined with the electronic component; and a heat dissipation body attached to the TIM and transferring heat of the electronic component to an outside of the space.

### CROSS-REFERENCE TO RELATED APPLICATIONS

This application is a continuation of International Patent Application No. PCT/KR2021/020026 filed on Dec. 28, 2021, which is based on and claims priority under 35 U.S.C. § 119 to Korean Patent Application No. 10-2020-0188341 filed on Dec. 30, 2020, in the Korean Intellectual Property Office, the disclosures of which are herein incorporated by reference in their entirety.

### 1. FIELD

Various embodiments of the disclosure relate to an electronic device including a heat dissipation structure.

### 2. DESCRIPTION OF RELATED ART

With the development of digital technology, various types of electronic devices such as a mobile communication terminal, a personal digital assistant (PDA), an electronic organizer, a smart phone, a tablet personal computer (tablet PC), and a wearable device are widely being used. In order to support and enhance functions of the electronic device, the hardware and/or software aspects of the electronic device are continuously being improved.

For example, the electronic device may provide a virtual reality (VR) that allows a user to have a real-like experience in a virtual world created by a computer. In addition, the electronic device may provide an augmented reality (AR) in which virtual information (or an object) is added to a real world, and a mixed reality (MR) in which the VR and the AR are mixed. The electronic device may include a head-up display for providing such VR and AR.

The electronic device has difficulty in discharging heat from a heat source disposed inside the electronic device due to a small surface area.

An electronic device including a heat dissipation structure according to various embodiments of the disclosure intends to transfer heat emitted by a heat source of the electronic device from the inside to an outer surface of the electronic device.

### SUMMARY

According to various embodiments, an electronic device may include a heat dissipation structure and the heat dissipation structure may include a first printed circuit board; a second printed circuit board spaced apart from the first printed circuit board to form a space; a first interposer and a second interposer surrounding the space; at least one electronic component disposed in the space and mounted on the first printed circuit board; a first thermal interface material (TIM) combined with the electronic component; and a heat dissipation body attached to the TIM and transferring heat of the electronic component to an outside from the space.

According to various embodiments, an electronic device may include a frame in which a display is disposed; a temple to allow the frame to be mounted on a user; and a heat dissipation structure disposed inside the temple, wherein the heat dissipation structure may include a first printed circuit board; a second printed circuit board spaced apart from the first printed circuit board to form a space; a first interposer and a second interposer surrounding the space; at least one electronic component disposed in the space and mounted on the first printed circuit board; a first thermal interface material (TIM) combined with the electronic component; and a heat dissipation body attached to the TIM and transferring heat of the electronic component to an outside from the space.

The electronic device including the heat dissipation structure according to various embodiments of the disclosure can transfer heat discharged from the electronic device to an outer surface of the electronic device, thereby suppressing a sudden temperature rise on a surface.

The electronic device including the heat dissipation structure according to various embodiments of the disclosure can provide an internal mounting space of the electronic device by simplifying the heat dissipation structure.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates a block diagram of an electronic device that receives wireless power in a network environment, according to various embodiments of the disclosure;

FIG. 2 illustrates the overall constitution of an electronic device according to various embodiments of the disclosure;

FIG. 3 illustrates an electronic device for changing a setting of a display panel according to various embodiments of the disclosure;

FIG. 4 illustrates a front side of a heat dissipation structure included in an electronic device according to various embodiments of the disclosure;

FIG. 5 illustrates a rear side of a heat dissipation structure included in an electronic device according to various embodiments of the disclosure;

FIG. 6 illustrates a cross-sectional view taken along the B-C direction in the heat dissipation structure of FIG. 4 according to various embodiments of the disclosure;

FIG. 7 illustrates a front side of a heat dissipation structure included in an electronic device according to various embodiments of the disclosure;

FIG. 8 illustrates a rear side of a heat dissipation structure included in an electronic device according to various embodiments of the disclosure;

FIG. 9 illustrates a cross-sectional view taken along the D-E direction in the heat dissipation structure of FIG. 7 according to various embodiments of the disclosure;

FIG. 10 illustrates a front side of an electronic device according to various embodiments of the disclosure; and

FIG. 11 illustrates a comparison of a temperature between a non-improved electronic device and an electronic device including a heat dissipation structure according to an embodiment of the disclosure.

### DETAILED DESCRIPTION

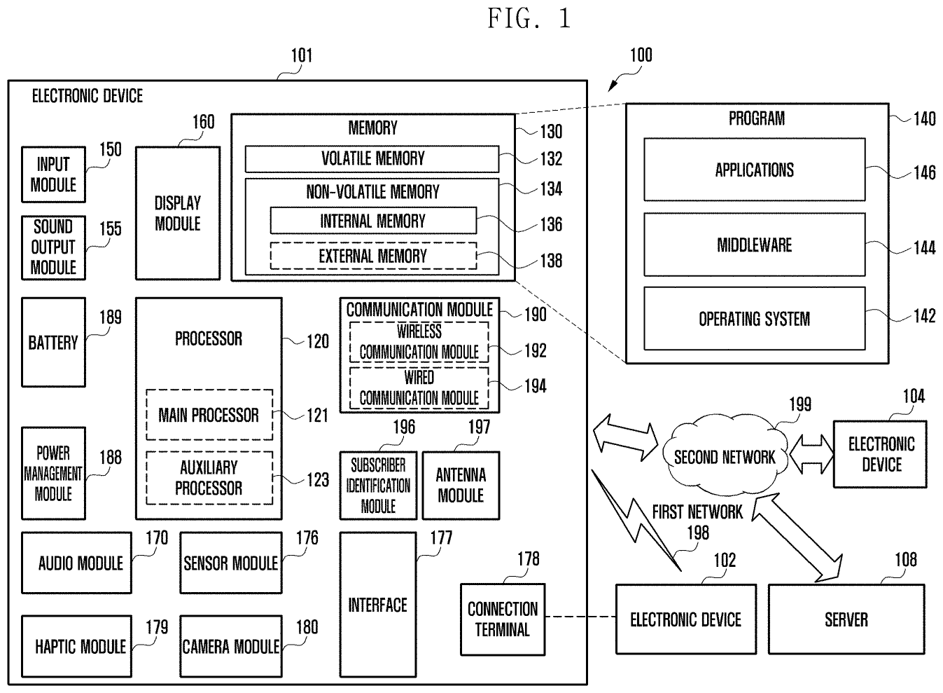

FIGS. 1 through 11, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

FIG. 1 is a block diagram illustrating an electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

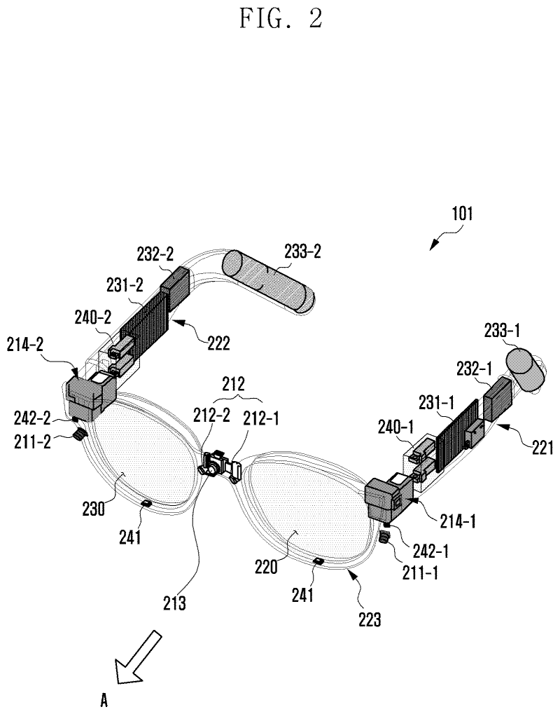

FIG. 2 illustrates the overall configuration of an electronic device (e.g., the electronic device 101 in FIG. 1) according to various embodiments of the disclosure.

The electronic device 101 may include a frame 223 that includes display modules 214-1 and 214-2 (e.g., the display module 160 in FIG. 1), glasses 220 and 230, camera modules (e.g., a shooting camera 213, an eye tracking camera 212, recognition cameras 211-1 and 211-2) (e.g., the camera module 180 in FIG. 1), microphones 241-1 and 241-2, and/or illuminance sensors 242-1 and 242-2, and may also include temples (e.g., a first temple 221 and a second temple 222) that are operatively connected to the frame through hinges 240-1 and 240-2 and include printed circuit boards 231-1 and 231-2, speakers 232-1 and 232-2 (e.g., the audio module 170 in FIG. 1), and/or batteries 233-1 and 233-2 (e.g., the battery 189 in FIG. 1).

According to an embodiment, the display modules 214-1 and 214-2 may provide visual information to the user through glasses (e.g., the first glass 220 and the second glass 230). The electronic device 101 may include the first glass 220 corresponding to the left eye and/or the second glass 230 corresponding to the right eye. According to an embodiment, the display modules 214-1 and 214-2 may include a display panel and/or a lens. For example, the display panel may include a transparent material such as glass or plastic.

According to an embodiment, the display modules 214-1 and 214-2 may include a condensing lens and/or a transparent waveguide, which are located on a portion of the glasses (e.g., the first glass 220 and the second glass 230). For example, the transparent waveguide may be located at least in part on a portion of the glass. According to an embodiment, the light emitted from the display modules 214-1 and 214-2 may be incident on one end of the glass through the first and second glasses 220 and 230, and the incident light may be transferred to the user through the waveguide formed in the glass. The waveguide may be made of glass, plastic, or polymer, and may include a nano-pattern, e.g., a polygonal or curved grating structure, formed on one inner or outer surface thereof. According to an embodiment, the incident light may be propagated or reflected inside the waveguide by the nano-pattern and provided to the user. According to an embodiment, the waveguide may include at least one diffractive element (e.g., a diffractive optical element (DOE) or a holographic optical element (HOE)) and/or a reflective element (e.g., a reflective mirror). According to an embodiment, using the at least one diffractive element or the reflective element, the waveguide may guide the display light emitted from the light source to the user's eyes.

According to an embodiment, a virtual object outputted through the display modules 214-1 and 214-2 may include information related to an application program executed in the electronic device 101 and/or information related to an external object located in a real space corresponding to an area determined as a user's field of view (FoV). For example, from image information related to the real space acquired through a camera (e.g., the shooting camera 213) of the electronic device 101, the electronic device 101 may identify an external object included in at least a portion corresponding to the area determined as the user's field of view. The electronic device 101 may output (or display) a virtual object related to the identified external object through the area determined as the user's field of view in the display area of the electronic device 101. The external object may include a thing existing in the real space. According to various embodiments, the display area in which the electronic device 101 displays the virtual object may include a portion (e.g., at least a portion of the display panel) of the display module (e.g., the first display module 214-1 or the second display module 214-2). According to an embodiment, the display area may correspond to at least a portion of the first glass 220 and/or the second glass 230. In various embodiments, the electronic device 101 may be worn on a user's head to provide the user with an image related to an augmented reality service. According to an embodiment, the electronic device 101 may provide the augmented reality service in which at least one virtual object is outputted to be superimposed on an area determined as the user's field of view. For example, the area determined as the user's field of view is an area determined to be recognizable through the electronic device 101 by the user wearing the electronic device 101, and may be an area including the overall or at least a part of a display module (e.g., the display module 160 in FIG. 1) of the electronic device 101. According to an embodiment, the electronic device 101 may include a plurality of glasses (e.g., the first glass 220 and/or the second glass 230) corresponding to both eyes of the user (e.g., left eye and/or right eye). The plurality of glasses may include at least a part of a display module (e.g., the first display module 214-1 and/or the second display module 214-2). For example, the first glass 220 corresponding to the user's left eye may include the first display module 214-1, and the second glass 230 corresponding to the user's right eye may include the second display module 214-2. The electronic device 101 may be configured, for example, in the form of at least one of glasses, goggles, a helmet, or a hat, but is not limited thereto.

According to another embodiment, when the display module 160 is a transparent ultra light emitting diode (uLED), the configuration of the waveguide in the glass (e.g., the first glass 220 and the second glass 230) may be omitted. According to another embodiment, the display module 160 may be formed of a transparent element, so the user may recognize a real space behind the display module 160 through the display module 160. The display module 160 may display a virtual object on at least a portion of the transparent element so that the virtual object can be seen by the user as if added to at least a portion of the real space. The first glass 220 and/or the second glass 230 included in the display module 160 may include a plurality of display panels corresponding to both eyes of the user (e.g., the left eye and/or the right eye).

According to an embodiment, the electronic device 101 may include a virtual reality (VR) device. When the electronic device 101 is the VR device, the first glass 220 may be the first display module 214-1, and the second glass 230 may be the second display module 214-2.

According to an embodiment, the electronic device 101 may enable the first display panel included in the first glass 220 and the second display panel included in the second glass 230 to be operated as independent components, respectively. For example, the electronic device 101 may determine the display performance of the first display panel, based on first configuration information, and may determine the display performance of the second display panel, based on second configuration information.

According to an embodiment, the at least one camera may include the shooting camera 213 for capturing an image corresponding to the user's field of view and/or measuring a distance to an object, the eye tracking camera 212 for identifying the direction of a user's gaze, and/or the gesture cameras 211-1 and 211-2 for recognizing a certain space.

According to an embodiment, the electronic device 101 may include the shooting camera 213 (e.g., an RGB camera) for capturing an image corresponding to the user's field of view and/or measuring a distance to an object, the eye tracking camera 212 for identifying the direction of a user's gaze, and/or the recognition cameras 211-1 and 211-2 (e.g., gesture cameras) for recognizing a certain space. According to an embodiment, using the shooting camera 213, the electronic device 101 may measure a distance to an object located in the front direction (e.g., a direction ‘A’) of the electronic device 101. According to an embodiment, in electronic device 101, a plurality of eye tracking cameras 212 may be disposed to correspond to both eyes of the user. The eye tracking camera 212 may detect the user's gaze direction (e.g., pupil motion). For example, the eye tracking camera 212 may include a first eye tracking camera 212-1 for tracking the gaze direction of the user's left eye, and a second eye tracking camera 212-2 for tracking the gaze direction of the user's right eye. According to an embodiment, using the recognition cameras 211-1 and 211-2, the electronic device 101 may detect a user gesture within a predetermined distance (e.g., a certain space). For example, there may be a plurality of recognition cameras 211-1 and 211-2, which may be disposed on both sides of the electronic device 101. Using at least one camera, the electronic device 101 may detect eyes corresponding to a primary eye and/or an auxiliary eye. For example, the eyes corresponding to the primary eye and/or the auxiliary eye may be detected based on the user's gaze direction with respect to the external object or the virtual object.

According to an embodiment, the shooting camera 213 may include a high resolution (HR) camera and/or a photo video (PV) camera. According to an embodiment, the eye tracking camera 212 may detect the user's pupil, thereby track the gaze direction, and may be utilized to move the center of a virtual image along the gaze direction. For example, the eye tracking camera 212 may be divided into the first eye tracking camera 212-1 corresponding to the left eye and the second eye tracking camera 212-2 corresponding to the right eye, which may have substantially the same performance and/or specifications. According to an embodiment, the recognition cameras 211-1 and 211-2 may be used for user's hand (gesture) detection and/or spatial recognition, and may include a global shutter (GS) camera. For example, in order to detect and track quick hand movements and/or minute finger movements, the recognition cameras 211-1 and 211-2 may include the GS camera with less screen afterimage such as a rolling shutter (RS) camera.

According to an embodiment, the electronic device 101 may display together a virtual object related to an augmented reality service, based on image information related to a real space acquired through a camera (e.g., the camera module 180 in FIG. 1) of the electronic device 101. According to an embodiment, the electronic device 101 may display the virtual object, based on a display module (e.g., the first display module 214-1 corresponding to the left eye and/or the second display module 214-2 corresponding to the right eye) disposed to correspond to both eyes of the user. According to an embodiment, the electronic device 101 may display the virtual object, based on predetermined setting information (e.g., resolution, frame rate, brightness, and/or display area).

The number and location(s) of one or more cameras (e.g., the shooting camera 213, the eye tracking camera 212, and/or the recognition camera 211-1, 211-2) included in the electronic device 101 shown in FIG. 2 may not be limited. For example, based on the form (e.g., shape or size) of the electronic device 101, the number and location(s) of one or more cameras (e.g., the shooting camera 213, the eye tracking camera 212, and/or the recognition camera 211-1, 211-2) may vary.

The electronic device 101 may include the microphones 241-1 and 241-2 for receiving a user's voice and ambient sounds. For example, the microphones 241-1 and 241-2 may be included in the audio module 170 shown in FIG. 1. The electronic device 101 may include the illuminance sensors 242-1 and 242-2 for identifying ambient brightness. For example, the illuminance sensors 242-1 and 242-2 may be included in the sensor module 176 shown in FIG. 1.

The first temple 221 and/or the second temple 222 may include the printed circuit board 231-1, 231-2 for transmitting an electrical signal to respective components of the electronic device 101, the speaker 232-1, 232-2 for outputting an audio signal, the battery 233-1, 233-2, and/or a hinge part 240-1, 240-2 coupled at least in part to the frame 223 of the electronic device 101. According to an embodiment, the speaker 232-1, 232-2 may include a first speaker 232-1 for transferring an audio signal to the user's left ear and a second speaker 232-2 for transferring an audio signal to the user's right ear. The speakers 232-1 and 232-2 may be included in the audio module 170 shown in FIG. 1. According to an embodiment, the electronic device 101 may include a plurality of batteries 233-1 and 233-2, which may supply power to the printed circuit boards 231-1 and 231-2 through a power management module (e.g., the power management module 188 in FIG. 1).

According to an embodiment, the first temple 221 and/or the second temple 222 may include the printed circuit board (PCB) 231-1, 231-2, the speaker 232-1, 232-2, and/or the battery 233-1, 233-2.

As a support member of the electronic device 101, the first temple 221 and/or the second temple 222 may support the frame 223 such that the electronic device 101 is worn on the user's body.

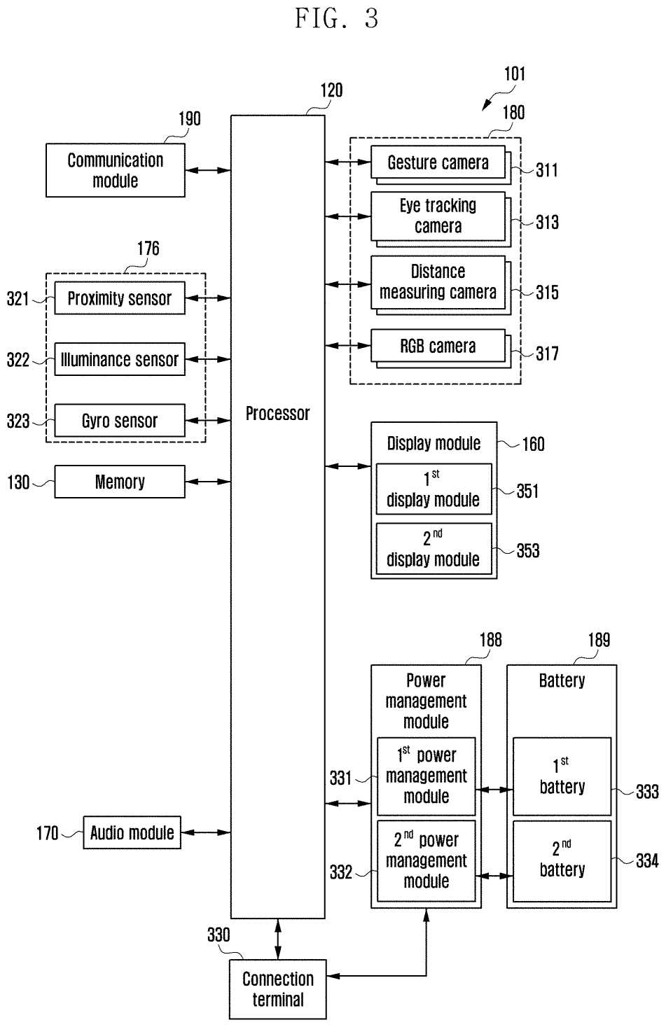

FIG. 3 illustrates an electronic device 101 (e.g., the electronic device 101 in FIG. 1) for changing a configuration of a display panel according to various embodiments of the disclosure.

With reference to FIG. 3, the electronic device 101 may include a processor 120 (e.g., the processor 120 in FIG. 1), a memory 130 (e.g., the memory 130 in FIG. 1), a display module 160 (e.g., the display module 160 in FIG. 1), an audio module 170 (e.g., the audio module 170 in FIG. 1), a sensor module 176 (e.g., the sensor module 176 in FIG. 1), a camera module 180 (e.g., the camera module 180 in FIG. 1), a power management module 188 (e.g., the power management module 188 in FIG. 1), a battery 189 (e.g., the battery 189 in FIG. 1), and/or a communication module (e.g., the communication module 190 in FIG. 1). According to an embodiment, the electronic device 101 may be connected to an external electronic device (not shown) through a connection terminal 330 (e.g., USB TYPE-C). For example, the power management module 188 of the electronic device 101 may receive power from the external electronic device through the connection terminal 330 and charge the battery 189. In another example, the processor 120 of the electronic device 101 may perform power line communication with the external electronic device through the connection terminal 330. According to an embodiment, the electronic device 101 may be composed of the frame 223 and the temples 221 and 222. According to an embodiment, the components of the electronic device 101 may be disposed on the frame 223 and/or the temples 221 and 222.

According to an embodiment, the processor 120 may control at least one other component (e.g., a hardware or software component) by executing a program (e.g., the program 140 in FIG. 1) stored in the memory 130, and perform various data processing or operations. According to an embodiment, the processor 120 may provide an augmented reality service to the user. The processor 120 may output at least one virtual object through the display module 160 such that the at least one virtual object can be superimposed on a real space corresponding to the field of view of the user wearing the electronic device 101.

According to an embodiment, the display module 160 of the electronic device 101 may include at least one glass (e.g., a first glass such as the first glass 220 in FIG. 2 and/or a second glass such as the second glass 230 in FIG. 2). According to an embodiment, the first glass 220 may include at least a portion of a first display module 351 (e.g., the first display module 214-1 in FIG. 2), and the second glass 230 may include at least a portion of a second display module 353 (e.g., the second display module 214-2 in FIG. 2). For example, each of the first and second display modules 351 and 353 may include a display panel. The display panel may be formed of a transparent element so that a user can recognize the real space through the display module 160. The display module 160 may display at least one virtual object on at least a portion of the display panel so that the virtual object can be seen by the user wearing the electronic device 101 as if the virtual object is added to the real space. For example, the user's field of view may include an angle or range at which the user can recognize an object. According to an embodiment, the display module 160 may include the first display module 351 corresponding to the user's left eye and the second display module 353 corresponding to the user's right eye. According to an embodiment, the processor 120 may load setting information (e.g., a resolution, a frame rate, a size of the display area, and/or a sharpness) related to the performance of the display module 160 from the memory 130, and adjust the performance of the display module 160 based on the setting information. According to an embodiment, such setting information may be individually determined for each display panel included in the display module 160. For example, the first display panel corresponding to the left eye may be set based on first setting information, and the second display panel corresponding to the right eye may be set based on second setting information. According to another embodiment, the setting information may set differently at least in part for the display panel included in the display module 160. For example, the electronic device 101 may set differently at least one of a resolution, a frame rate, or a sharpness of the display module 160. According to an embodiment, the electronic device 101 may reduce power consumption by changing at least in part the setting of the display module 160.

According to an embodiment, the audio module 170 may convert a sound into an electric signal or, conversely, convert an electric signal into a sound, based on the control of the processor 120. For example, the audio module 170 may include the speakers 232-1 and 232-2 shown in FIG. 2 and/or the microphone 241 shown in FIG. 2.

According to an embodiment, the sensor module 176 of the electronic device 101 may include a proximity sensor 321, an illuminance sensor 322 (e.g., the illuminance sensor 242 in FIG. 2), and/or a gyro sensor 323. According to an embodiment, the proximity sensor 321 may detect an object in the proximity of the electronic device 101. The illuminance sensor 322 may measure a brightness level around the electronic device 101. According to an embodiment, the processor 120 may identify the brightness level around the electronic device 101 by using the illuminance sensor 322 and, based on the brightness level, change the brightness-related configuration information of the display module 160. For example, when the ambient brightness is greater than the preset brightness, the processor 120 may configure the brightness level of the display module 160 to be higher so as to increase the user's visibility. According to an embodiment, the gyro sensor 323 may detect the posture and position of the electronic device 101. For example, the gyro sensor 323 may detect whether the electronic device 101 is properly worn on the user's head. In another example, the gyro sensor 323 may detect the motion of the electronic device 101 or the user wearing the electronic device 101.

According to an embodiment, the electronic device 101 may perform wireless communication with another electronic device (e.g., the electronic devices 102 and 104 in FIG. 1) through the communication module 190 (e.g., a wireless communication circuit). For example, the electronic device 101 may perform wireless communication with a portable electronic device (e.g., a smartphone) to exchange commands and/or data with each other. According to an embodiment, the electronic device 101 may be controlled at least in part by another electronic device (e.g., a portable electronic device). For example, the electronic device 101 may perform at least one function under the control of another electronic device.

According to various embodiments, based on the control of another electronic device (e.g., the electronic devices 102 and 104 in FIG. 1) connected wirelessly and/or by wire, the electronic device 101 may change at least a part of the configurations of the display panel. According to an embodiment, the electronic device 101 may transmit, to other electronic device, information related to primary/auxiliary eyes (e.g., information on a distance to an object located in the real space, user's eye tracking information, user's gesture information) acquired through the camera (e.g., the camera module 180 in FIG. 1) of the electronic device 101. Based on the primary/auxiliary eyes related information received from the electronic device 101, the other electronic device may transmit setting information of the display panel included in the glass (e.g., the first glass 220 and/or the second glass 230) corresponding to the primary or auxiliary eye to the electronic device 101. The electronic device 101 may change at least a part of the settings of the display panel, based on the setting information of the display panel received from the other electronic device. For example, the settings of the display panel may be changed to lower the quality of the display panel, and at least a part of the configurations may be changed so as not to be felt by the user. According to an embodiment, the electronic device 101 may reduce the resolution of the display panel, decrease the frame rate, or adjust the size and position of the display area of the display panel.

According to an embodiment, the camera module 180 of the electronic device 101 may include a gesture camera 311, an eye tracking camera 313, a distance measuring camera 315 (e.g., depth camera), and/or an RGB camera 317. According to an embodiment, the gesture camera 311 may detect a user's motion. The recognition cameras 211-1 and 211-2 shown in FIG. 2 may include the gesture camera 311. For example, at least one gesture camera 311 may be disposed in the electronic device 101, and may detect a user's hand motion within a preset distance. The gesture camera 311 may include a simultaneous localization and mapping (SLAM) camera for recognizing information (e.g., location and/or direction) related to a surrounding space of the electronic device 101. The gesture recognition area of the gesture camera 311 may be set based on a photographing range of the gesture camera 311. According to an embodiment, the eye tracking camera 313 (e.g., the eye tracking camera 212 in FIG. 2) may track the movement of the user's left and right eyes. According to an embodiment, using the eye tracking camera 313, the processor 120 may identify the gaze direction of the left eye and the gaze direction of the right eye. For example, the eye tracking camera 313 may include the first eye tracking camera 212-1 for identifying the gaze direction of the left eye and the second eye tracking camera 212-2 for identifying the gaze direction of the right eye. According to an embodiment, the processor 120 may determine the primary eye and the auxiliary eye, based on the gaze directions of the left and right eyes. According to an embodiment, the distance measuring camera 315 may measure a distance to an object located in front of the electronic device 101. The shooting camera 213 shown in FIG. 2 may include the distance measuring camera 315. The distance measuring camera 315 may include a time-of-flight (TOF) camera and/or a depth camera. According to another embodiment, the electronic device 101 may measure a distance to an object by using the distance measuring camera 315 and, if the distance is equal to or greater than a threshold value, change the settings of the display panel. For example, when the distance to the object is smaller than the threshold value, the electronic device 101 may maintain the display performance of the display panel. According to an embodiment, the electronic device 101 may recognize one of objects located in the user's gaze direction (e.g., FOV) through the eye tracking camera 313 and then calculate the distance to the object as a depth through the depth camera or measure the distance to the object through the TOF camera. According to an embodiment, the red green blue (RGB) camera 317 may detect color-related information of an object and information on a distance to the object. According to an embodiment, the electronic device 101 may include one type of camera in which the distance measuring camera 315 and the RGB camera 317 are integrated. For example, the shooting camera 213 shown in FIG. 2 may include the distance measuring camera 315 and/or the RGB camera 317. According to an embodiment, the gesture camera 311, the eye tracking camera 313, the distance measuring camera 315, and/or the RGB camera 317 included in the camera module 180 may be individually included in the electronic device 101, or some of them may be implemented as an integrated camera. For example, the distance measuring camera 315 and the RGB camera 317 may be implemented as one integrated camera.

According to an embodiment, the power management module 188 may manage power supplied to the electronic device 101. The power management module 188 may include a plurality of power management modules (e.g., a first power management module 331 and a second power management module 332). At least a part of the first power management module 331 or the second power management module 332 may be directly connected to the processor 120 to supply power. At least a part of the first power management module 331 or the second power management module 332 may receive power from an external electronic device through the connection terminal 330 (e.g., TYPE-C) and then charge the battery 189 or supply power to other components of the electronic device 101. According to an embodiment, the electronic device 101 may charge the battery 188 by receiving power from an external electronic device through a wireless charging method. According to an embodiment, the power management module 188 may be electrically connected to components (e.g., the memory 130, the display module 160, the audio module 170, the sensor module 176, the camera module 180, and/or the communication module 190) of the electronic device 101. For example, the power management module 188 may provide power of the battery 189 to components of the electronic device 101, based on the control of the processor 120. According to an embodiment, the electronic device 101 may receive power from the first battery 333 through the first power management module 331 and receive power from the second battery 334 through the second power management module 332. According to an embodiment, the processor 120 may change at least in part the settings of the display module 160, based on information acquired using the at least one camera 311, 313, 315, and 317 included in the camera module 180, thereby managing power consumption.

According to an embodiment, the battery 189 may be charged by receiving power or discharged by providing power under the control of the power management module 188. According to an embodiment, the battery 189 may include a plurality of batteries (e.g., a first battery 333 and a second battery 343). For example, the plurality of batteries (e.g., the first battery 333 and the second battery 343) may be disposed in the frame 223 and the temple (e.g., the first temple 221 and/or the second temple 222). According to an embodiment, the first battery 333 may be disposed in the first temple 221, and the second battery 343 may be disposed in the second temple 222.

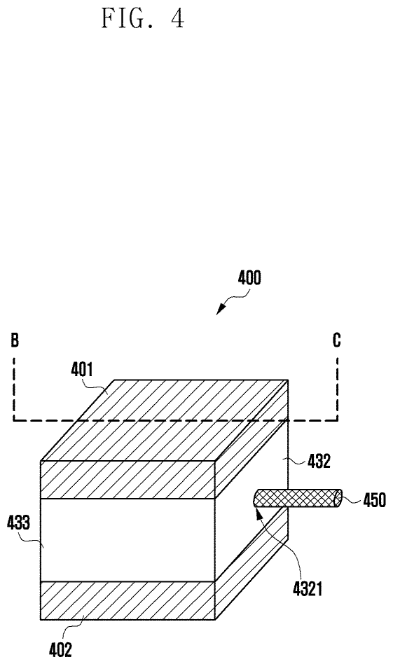

FIG. 4 illustrates a front side of a heat dissipation structure 400 included in an electronic device 101 according to various embodiments of the disclosure.

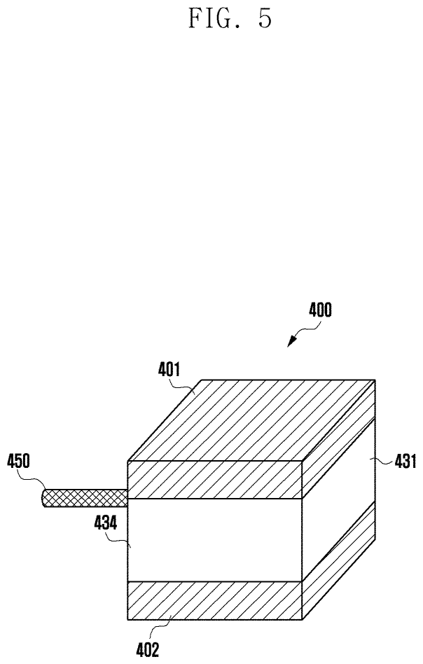

FIG. 5 illustrates a rear side of a heat dissipation structure 400 included in an electronic device 101 according to various embodiments of the disclosure. With reference to FIGS. 4 and 5, the heat dissipation structure 400 may include a first printed circuit board 401, a second printed circuit board 402, a first interposer 431, a second interposer 432, a third interposer 433, a fourth interposer 434, and a heat dissipation body 450.

The first printed circuit board 401 and the second printed circuit board 402 may be spaced apart to form a space. The first interposer 431, the second interposer 432, the third interposer 433, and the fourth interposer 434 may surround the space between the first printed circuit board 401 and the second printed circuit board 402.

At least one of the first interposer 431, the second interposer 432, the third interposer 433, and the fourth interposer 434 may include a through hole for allowing the heat dissipation body 450 to be connected to the outside from the inside of the heat dissipation structure 400.

In various embodiments, the second interposer 432 may include a through hole 4321 so that the heat dissipation body 450 can be connected to the outside from the inside of the heat dissipation structure 400.

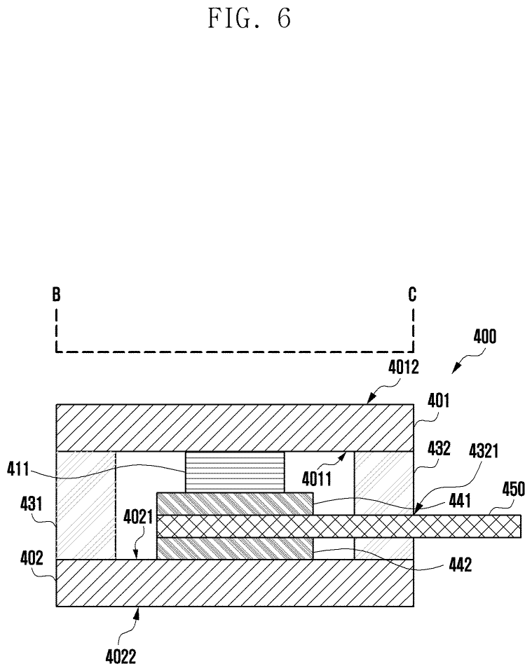

FIG. 6 illustrates a cross-sectional view taken along the B-C direction in the heat dissipation structure 400 of FIG. 4 according to various embodiments of the disclosure.

With reference to FIGS. 4, 5 and 6, the heat dissipation structure 400 may include the first printed circuit board 401, the second printed circuit board 402, the first interposer 431, the second interposer poser 432, the third interposer 433, the fourth interposer 434, a first thermal interface material (TIM) 441, a second TIM 442, and the heat dissipation body 450.

The first printed circuit board 401 and/or the second printed circuit board 402 may be identical with the printed circuit boards 231-1 and 231-2 shown in FIG. 2. The first printed circuit board 401 and/or the second printed circuit board 402 may have a plate shape.

The first printed circuit board 401 may include at least one electronic component 411 on an upper surface thereof. A lower surface 4012 of the first printed circuit board 401 may be a component side. The electronic component 411 (e.g., the processor 120 in FIG. 1) may be disposed on the upper surface 4011 (e.g., the surface facing the second printed circuit board 402) of the first printed circuit board 401. The electronic component 411 disposed on the upper surface 4011 of the first printed circuit board 401 may be an electronic component that emits heat, such as the memory 130 and/or the communication module 190 as well as the processor 120. The first printed circuit board 401 may include a solder side on the lower surface 4012.

The second printed circuit board 402 may include at least one electronic component (not shown) on an upper surface 4021 (e.g., the surface facing the first printed circuit board 401) thereof. A lower surface 4022 of the second printed circuit board 402 may be a component side. The electronic component (not shown, e.g., the processor 120 in FIG. 1) may be disposed on the upper surface 4021 of the second printed circuit board 402. The electronic components (not shown) disposed on the upper surface 4021 of the second printed circuit board 402 may be an electronic component that emits heat, such as the memory 130 and/or the communication module 190 as well as the processor 120. The second printed circuit board 402 may include a soldering side on the lower surface 4022.

The first printed circuit board 401 and the second printed circuit board 402 may be spaced apart to form a space. The first interposer 431 and the second interposer 432 may maintain the spaced space.

In various embodiments, the first interposer 431 and the second interposer 432 may surround the spaced space. The first interposer 431 and/or the second interposer 432 may be an interposer printed circuit board, which electrically connects the first printed circuit board 401 and the second printed circuit board 402.

In various embodiments, although FIG. 6 depicts the first interposer 431 and/or the second interposer 432 to show a cross-section of the heat dissipation structure 400 of the electronic device 101, the heat dissipation structure 400 may further include any other interposer (e.g., the third interposer 433 or the fourth interposer 434) in addition to the first interposer 431 and/or the second interposer 432 to surround the space between the first printed circuit board 401 and the second printed circuit board 402. For example, if the first printed circuit board 401 and the second printed circuit board 402 have rectangular plane shapes, the first and second printed circuit boards 401 and 402 may be spaced apart by and form the space surrounded by four interposers.

In various embodiments, the second interposer 432 may include the through hole 4321 that allows the heat dissipation body 450 to be connected to the outside of the heat dissipation structure 400.

The through hole 4321 may be formed in at least a portion of the second interposer 432 such that the heat dissipation body 450 contained inside the heat dissipation structure 400 and transferring heat outwards can extend to the outside from the inside of the heat dissipation structure 400.

In various embodiments, the upper surface 4011 of the first printed circuit board 401 may be disposed to face the upper surface 4021 of the second printed circuit board 402. The lower surface 4012 of the first printed circuit board 401 and/or the lower surface 4022 of the second printed circuit board 402 may face the outside of the heat dissipation structure 400.

The first TIM 441 may be disposed on the upper surface 4011 of the first printed circuit board 401 or on the electronic component 411 (e.g., the processor 120) placed on the upper surface 4011 of the first printed circuit board 401. The second TIM 442 may be disposed on the upper surface 4021 of the second printed circuit board 402 or on an electronic component (not shown) placed on the upper surface 4021 of the second printed circuit board 402. The first TIM 441 and/or the second TIM 442 may transfer heat generated by the electronic component 411 (e.g., the processor 120) to the heat dissipation body 450.

The first TIM 441 and/or the second TIM 442 may include, for example, a compound, a gel, a solder, and/or a metal material.

The heat dissipation body 450 may be a heat sink or a heat pipe. The heat dissipation body 450 may transfer heat received from the first TIM 441 and/or the second TIM 442 to the outside of the heat radiation structure 400. In this case, the heat dissipation body 450 may be disposed to extend in the direction of the batteries 233-1 and 233-2 shown in FIG. 2.

Although not shown, the heat dissipation body 450 may be disposed to extend in at least one direction when viewed from above the electronic component 411 (e.g., the processor 120). For example, with reference to FIG. 2, the heat dissipation body 450 may extend in the direction of the batteries 233-1 and 233-2 or in the direction of the frame 223.

With reference to FIGS. 2 and 6, a position where the heat dissipation structure 400 including the first printed circuit board 401 and/or the second printed circuit board 402 is disposed may be identical with a position where the printed circuit board 231-1 or 231-2 of FIG. 2 is disposed.

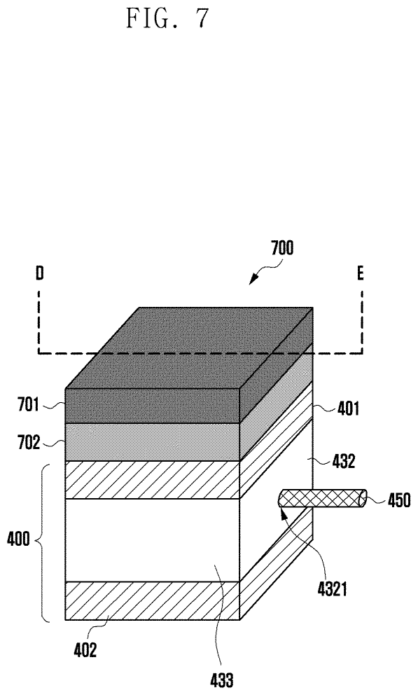

FIG. 7 illustrates a front side of a heat dissipation structure 700 included in an electronic device 101 according to various embodiments of the disclosure.

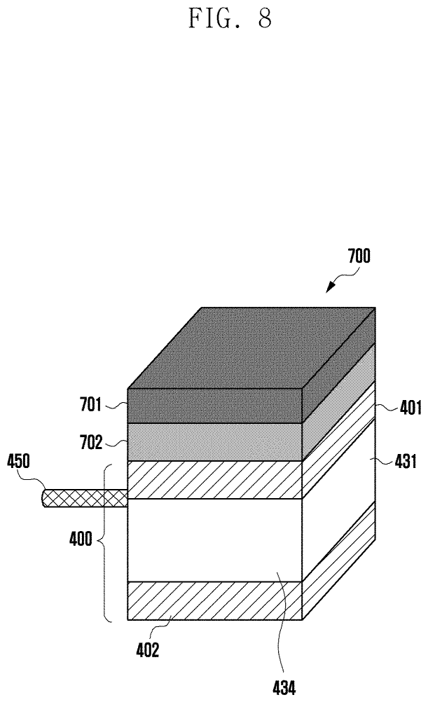

FIG. 8 illustrates a rear side of a heat dissipation structure 700 included in an electronic device 101 according to various embodiments of the disclosure.

With reference to FIGS. 7 and 8, the heat dissipation structure 700 may include the first printed circuit board 401, the second printed circuit board 402, the first interposer 431, the second interposer 432, the third interposer 433, the fourth interposer 434, the heat dissipation body 450, a cover 701, and a third TIM 702.

Compared to the heat dissipation structure 400 shown in FIG. 4, the heat dissipation structure 700 shown in FIG. 7 may further include the cover 701 and the third TIM 702.

The first printed circuit board 401 and the second printed circuit board 402 may be spaced apart to form a space. The first interposer 431, the second interposer 432, the third interposer 433, and the fourth interposer 434 may surround the space between the first printed circuit board 401 and the second printed circuit board 402.

At least one of the first interposer 431, the second interposer 432, the third interposer 433, and the fourth interposer 434 may include a through hole for allowing the heat dissipation body 450 to be connected to the outside from the inside of the heat dissipation structure 700.

In various embodiments, the second interposer 432 may include a through hole 4321 so that the heat dissipation body 450 can be connected to the outside from the inside of the heat dissipation structure 700.

The heat dissipation structure 700 may include the third TIM 702 and the cover 701 on the first printed circuit board 401. The third TIM 702 may be disposed between the first printed circuit board 401 and the cover 701 and transfer heat from the first printed circuit board 401 to the cover 701.

In various embodiments, the cover 701 may be disposed in a direction opposite to the direction of the user's body (e.g., face) when the electronic device 101 is worn.

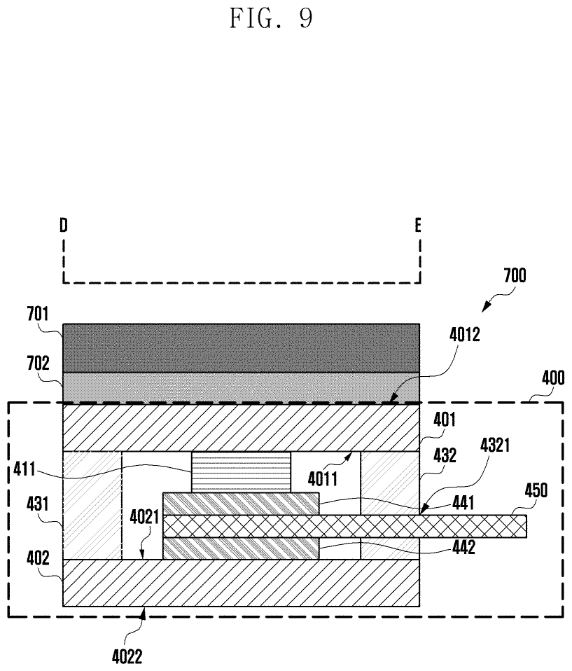

FIG. 9 illustrates a cross-sectional view taken along the D-E direction in the heat dissipation structure 700 of FIG. 7 according to various embodiments of the disclosure.

Compared to the heat dissipation structure 400 shown in FIG. 6, the heat dissipation structure 700 shown in FIG. 9 may further include the cover 701 and the third TIM 702.

The cover 701 may be combined with the heat dissipation structure 400 shown in FIG. 6 through the third TIM 702.

The cover 701 may constitute a part of the temple of the electronic device 101. The cover 701 may be made of, for example, resin and/or metal.

The third TIM 702 may be a graphite material. The third TIM 702 may be a thermal pad.

The third TIM 702 may be attached to and/or disposed on the lower surface 4012 of the first printed circuit board 401 to transfer heat generated by the first printed circuit board 401 to the cover 701.

Although not shown, together with the cover 701, the third TIM 702 may be attached to and/or disposed on the lower surface 4022 of the second printed circuit board 402 to transfer heat generated by the second printed circuit board 401 to the cover 701.

Between the lower surface 4012 of the first printed circuit board 401 and the third TIM 702 and/or between the third TIM 702 and the cover 701, an adhesive material (e.g., an adhesive tape or adhesive bond) may be interposed.

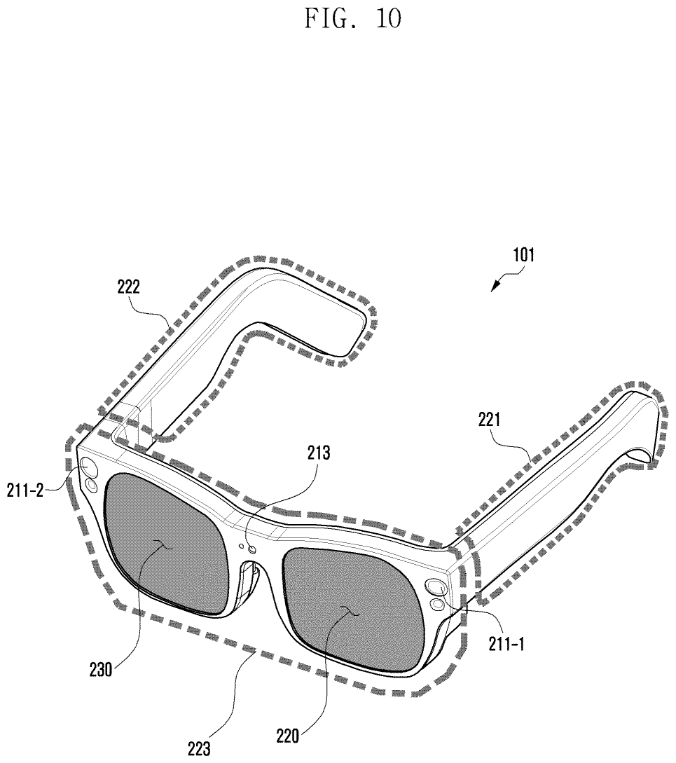

FIG. 10 illustrates a front side of an electronic device according to various embodiments of the disclosure.

The electronic device 101 may be composed of the frame 223 and the temple(s) (e.g., the first temple 221 and/or the second temple 222), and the frame 223 and the temples 221 and 222 may be in an operatively connected state. For example, the frame 223 and the temples 221 and 222 may be operatively connected through a hinge unit (e.g., the hinges 240-1 and 240-2 in FIG. 2). For example, the frame 223 may be mounted at least in part on the user's nose, and may include the display module 160 and the camera module (e.g., the camera module 180 in FIG. 1). The temples 221 and 222 may include a support member mounted on the user's ear, and may include the first temple 221 mounted on the left ear and/or the second temple 222 mounted on the right ear.

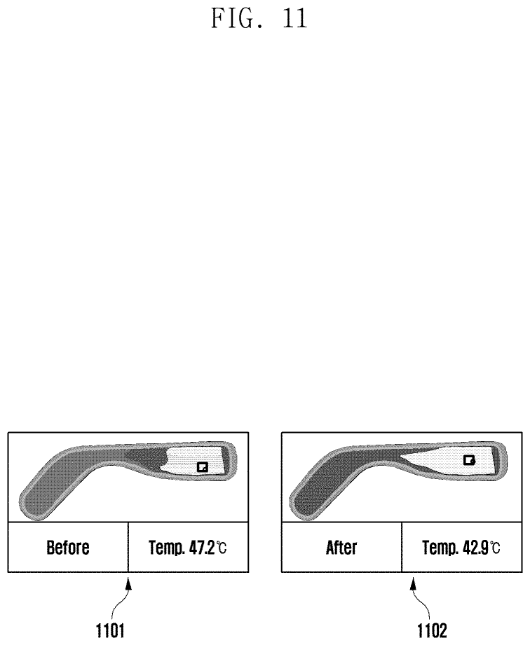

FIG. 11 illustrates a comparison of a temperature between a electronic device that does not include a heat dissipation structure (herein referred to as “non-improved electronic device”) and an electronic device 101 including a heat dissipation structure according to an embodiment of the disclosure.

A reference numeral 1101 shows a view indicating a temperature of heat generated in the non-improved electronic device, and a reference numeral 1102 shows a view indicating the temperature of heat generated in the electronic device 101 according to an embodiment of the disclosure.

In case of the reference numeral 1101, the non-improved electronic device according to a comparative example may include a printed circuit board inside the temple. In non-improved electronic devices, the surface temperature of the temple measured during the execution of an application and/or function may be up to 47.2° C.

In case of the reference numeral 1102, the electronic device 101 according to an embodiment of the disclosure may include the printed circuit boards 231-1 and 231-2 inside the temples (e.g., the first temple 221 and/or the second temple 222), and the printed circuit boards 231-1 and 231-2 may include the heat dissipation structure (400 in FIG. 4 or 700 in FIG. 7).

When the same application and/or function as executed in the non-improved electronic device are executed in the electronic device 101 according to the embodiment of the disclosure, the measured surface temperature of the temple may be up to 42.9° C.

Compared to the non-improved electronic device, the electronic device 101 including the heat dissipation structure (400 in FIG. 4 or 700 in FIG. 7) of the disclosure may lower the surface temperature generated in the electronic device 101.

According to various embodiments, in an electronic device including a heat dissipation structure 400, the heat dissipation structure 400 may include a first printed circuit board 401, a second printed circuit board 402 spaced apart from the first printed circuit board 401 to form a space, a first interposer 431 and a second interposer 432 surrounding the space, at least one electronic component 411 disposed in the space and mounted on the first printed circuit board 401, a first thermal interface material (TIM) 441 combined with the electronic component 411, and a heat dissipation body 450 attached to the TIM 441 and transferring heat of the electronic component 411 to an outside from the space.

According to various embodiments, the first printed circuit board 401 and the second printed circuit board 402 may each have an upper surface as a component side and a lower surface as a solder side, and the upper surfaces of the first and second printed circuit boards 401 and 402 may face each other and be spaced apart from each other to form the space.

According to various embodiments, at least one of the first and second interposers 431 and 432 may have a through hole 4321 that allows the heat dissipation body 450 to be connected to the outside from an inside of the heat dissipation structure 400.

According to various embodiments, the upper surface of the second printed circuit board 402 may include at least one electronic component 411.

According to various embodiments, the heat dissipation structure 400 may further include a second TIM 442 combined with the upper surface of the second printed circuit board 402.

According to various embodiments, the first TIM 441 and the second TIM 442 may include at least one of a compound, a gel, a solder, and a metal.

According to various embodiments, the heat dissipation body 450 may be disposed between the first TIM 441 and the second TIM 442.

According to various embodiments, the heat dissipation body 450 may be one of a heat sink and a heat pipe.

According to various embodiments, the heat dissipation structure 400 may further include a thermal pad combined with at least a portion of the lower surface of the first printed circuit board 401 and the lower surface of the second printed circuit board 402.

According to various embodiments, the heat dissipation structure 400 may further include a cover 701 combined with at least a portion of the thermal pad.

According to various embodiments, the thermal pad may be made of graphite, and the cover 701 may be made of resin and/or metal.

According to various embodiments, the electronic device 101 may be augmented reality (AR) glasses.

According to various embodiments, the AR glasses may include a frame 223 in which a display (e.g., the first display module 214-1 or 351 and/or the second display module 214-2 or 353) is disposed, and a temple 221 or 222 in which the heat dissipation structure 400 is disposed.

According to various embodiments, the temples 221 and 222 may further include a speaker 232-1 and 232-2 and a battery 233-1 and 233-2.

According to various embodiments, the frame 223 may further include a camera.

According to various embodiments, an electronic device 101 may include a frame 223 in which a display (e.g., the first display module 214-1 or 351 and/or the second display module 214-2 or 353) is disposed, a temple 221 or 222 to allow the frame 223 to be mounted on a user, and a heat dissipation structure 400 disposed inside the temple 221 or 222, wherein the heat dissipation structure 400 may include a first printed circuit board 401, a second printed circuit board 402 spaced apart from the first printed circuit board 401 to form a space, a first interposer 431 and a second interposer 432 surrounding the space, at least one electronic component 411 disposed in the space and mounted on the first printed circuit board 401, a first thermal interface material (TIM) 441 combined with the electronic component 411, and a heat dissipation body 450 attached to the TIM 441 and transferring heat of the electronic component 411 to an outside from the space.

According to various embodiments, at least one of the first and second interposers 431 and 432 may have a through hole 4321 that allows the heat dissipation body 450 to be connected to the outside from an inside of the heat dissipation structure.

According to various embodiments, the heat dissipation structure 400 may further include a second TIM 442 combined with an upper surface of the second printed circuit board 402.

According to various embodiments, the heat dissipation body 450 may be disposed between the first TIM 441 and the second TIM 442.

According to various embodiments, the first printed circuit board 401 and the second printed circuit board 402 may each have an upper surface as a component side and a lower surface as a solder side, and the upper surfaces of the first and second printed circuit boards 401 and 402 may face each other and be spaced apart from each other to form the space.

The electronic device according to various embodiments of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C” may include any one of, or all possible combinations of the items enumerated together in a corresponding one of the phrases. As used herein, such terms as “1^{st}” and “2^{nd}”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic”, “logic block”, “part”, or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

Although the present disclosure has been described with various embodiments, various changes and modifications may be suggested to one skilled in the art. It is intended that the present disclosure encompass such changes and modifications as fall within the scope of the appended claims.

What is claimed is:

1. An electronic device including a heat dissipation structure, the heat dissipation structure comprising:
a first printed circuit board;
a second printed circuit board spaced apart from the first printed circuit board to form a space;
a first interposer and a second interposer together surrounding the space;
at least one electronic component disposed in the space and mounted on the first printed circuit board;
a first thermal interface material (TIM) combined with the electronic component; and
a heat dissipation body attached to the first TIM and configured to transfer heat of the electronic component to an outside of the space.

2. The electronic device of claim 1, wherein the first printed circuit board and the second printed circuit board each include an upper surface as a component side and a lower surface as a solder side, and
wherein the upper surfaces of the first and second printed circuit boards face each other and are spaced apart from each other to form the space.

3. The electronic device of claim 1, wherein at least one of the first and second interposers includes a through hole that allows the heat dissipation body to be connected to the outside from an inside of the heat dissipation structure.

4. The electronic device of claim 2, wherein the upper surface of the second printed circuit board includes at least one electronic component.

5. The electronic device of claim 4, wherein the heat dissipation structure further comprises a second TIM combined with the upper surface of the second printed circuit board.

6. The electronic device of claim 5, wherein the first TIM and the second TIM include at least one of a compound, a gel, a solder, or a metal.

7. The electronic device of claim 6, wherein the heat dissipation body is disposed between the first TIM and the second TIM.

8. The electronic device of claim 7, wherein the heat dissipation body is one of a heat sink or a heat pipe.

9. The electronic device of claim 2, wherein the heat dissipation structure further comprises a thermal pad combined with at least a portion of the lower surface of the first printed circuit board and the lower surface of the second printed circuit board.

10. The electronic device of claim 9, wherein the heat dissipation structure further comprises a cover combined with at least a portion of the thermal pad.

11. The electronic device of claim 10, wherein the thermal pad is composed of graphite, and the cover is composed of resin or metal.

12. The electronic device of claim 1, wherein the electronic device is augmented reality (AR) glasses.

13. The electronic device of claim 12, wherein the AR glasses include:
a frame;
a display disposed in the frame; and
a temple in which the heat dissipation structure is disposed.

14. The electronic device of claim 13, wherein the temple further includes a speaker and a battery.

15. The electronic device of claim 13, wherein the frame further includes a camera.

16. An electronic device comprising:
a frame;
a display disposed in the frame;
a temple configured to allow the frame to be mounted on a user; and
a heat dissipation structure disposed inside the temple,
wherein the heat dissipation structure comprises:
a first printed circuit board;
a second printed circuit board spaced apart from the first printed circuit board to form a space;
a first interposer and a second interposer together surrounding the space;
at least one electronic component disposed in the space and mounted on the first printed circuit board;
a first thermal interface material (TIM) combined with the electronic component; and
a heat dissipation body attached to the TIM and configured to transfer heat of the electronic component to an outside of the space.

17. The electronic device of claim 16, wherein at least one of the first and second interposers include a through hole that allows the heat dissipation body to be connected to the outside from an inside of the heat dissipation structure.

18. The electronic device of claim 16, wherein the heat dissipation structure further comprises a second TIM combined with an upper surface of the second printed circuit board.

19. The electronic device of claim 18, wherein the heat dissipation body is disposed between the first TIM and the second TIM.

20. The electronic device of claim 16, wherein the first printed circuit board and the second printed circuit board each have an upper surface as a component side and a lower surface as a solder side, and
wherein the upper surfaces of the first and second printed circuit boards face each other and are spaced apart from each other to form the space.
